(19) United States
(12) Patent Application Publication
(10) Pub. No.: US 2011/0049557 A1
(43) Pub. Date: Mar. 3, 2011

(54) OPTICAL DEVICE AND METHOD OF MANUFACTURING THE SAME

(76) Inventor: Hu MENG, Osaka (JP)

(21) Appl. No.: 12/820,684

(22) Filed: Jun. 22, 2010

(30) Foreign Application Priority Data
Sep. 2, 2009 (JP) 2009-202932

(51) Int. Cl. H01L 33/48; H01L 31/02; H01L 21/50; H01L 31/18

(52) U.S. Cl. 257/99; 257/434; 438/26; 438/64; 257/E33.056; 257/E21.499; 257/E31.11

(57) ABSTRACT

An optical device having following components is disclosed. A semiconductor substrate has an element region formed on its upper side. A light transmitting insulator film covers an element region and has at least one recessed portion located in a region outside the element region. At least one protruding portion is provided in a region on the light transmitting insulator film outside the element region and inside the recessed portion. A light transmitting member covers the element region from above and is provided on the protruding portion. A light transmitting adhesive is filled in between the light transmitting insulator film and the light transmitting member.

### CROSS REFERENCE TO RELATED APPLICATION

This application claims priority from Japanese Patent Application JP 2009-202932 filed on Sep. 2, 2009, the disclosure of which application is hereby incorporated by reference into this application in its entirety for all purposes.

### BACKGROUND

The technique described in the present specification relates to an optical device and a method of manufacturing the same. In more particular but not limitatively, the optical device includes an image sensor such as a charge coupled device (CCD) and a complementary metal oxide semiconductor (CMOS); a light receiving element such as a photo diode, a photo transistor, and a photo integrated circuit (IC); and a light emitting element such as a light emitting diode (LED) and a semiconductor laser.

In recent years, as a package structure of the optical device such as a solid state imaging device, a direct attachment structure has been proposed instead of a conventional hollow package structure. In the present specification, the term “direct attachment structure” refers to a structure in which a light transmitting board is directly attached by a light transmitting adhesive to a light receiving/emitting region provided on a semiconductor substrate. With such a direct attachment structure, the sensitivity of the optical device can be enhanced by making uniform the refractive indices of the light transmitting board, the light transmitting adhesive, and the light transmitting film formed on the semiconductor substrate. Moreover, by employing the direct attachment structure, it is possible to more easily reduce the size and the thickness of the package, and to prevent entry of dust into the light receiving/emitting region during the manufacturing process of the optical device, for example.

The optical device having such a direct attachment structure is manufactured by applying a light transmitting adhesive onto a light receiving/emitting region of a semiconductor substrate with an electrode mounted thereon and attaching a light transmitting member (board) formed of a glass plate or the like to that region. However, since the light transmitting adhesive is in a liquid state when attaching the light transmitting member, the light transmitting adhesive may cover the electrode mounted on the semiconductor substrate depending on the applied amount of the light transmitting adhesive, which may affect the reliability of the optical device.

In view of such a problem, Japanese Patent Publication No. 2007-150266 proposes a solution for preventing the light transmitting adhesive from flowing over to a region where the adhesive is not necessary. In this connection, FIG. 12 is a view in vertical section showing a configuration of such a conventional solid state imaging element having a direct attachment structure.

According to the conventional solid state imaging element as shown in FIG. 12, a light transmitting board 102 is directly attached by a light transmitting adhesive 110 onto a semiconductor substrate 104 having a light receiving section 101 and electrode sections 107 formed thereon, so as to cover the light receiving section 101 from above, whereby the direct attachment structure can be achieved. According to the conventional solid state imaging element, a flattened film 103 is formed on the semiconductor substrate 104 so as to cover the light receiving section 101. Protruding portions 106 extend on portions of the flattened film 103 located between the light receiving section 101 and the electrode sections 107 as viewed from above. Since the protruding portions 106 block the light transmitting adhesive 110 when the light transmitting board 102 is bonded to the semiconductor substrate 104, the light transmitting adhesive 110 will not easily flow into the electrode sections 107.

Japanese Patent Publication No. 2009-135401 proposes another solid state imaging element, in which a plurality of protruding portions 106 are provided for one side of the semiconductor substrate 104. With this configuration, even when the light transmitting adhesive 110 is applied in somewhat increased amount, the light transmitting adhesive 110 tends to flow into a space between two adjacent protruding portions 106 extending adjacent to each other. Thus, the light transmitting adhesive 110 does not easily flow into the electrode sections 107.

### SUMMARY

In the conventional solid state imaging element as shown in FIG. 12, however, since the height each of the protruding portions 106 is only in the order of several micrometers, even if the protruding portions 106 are formed on the semiconductor substrate 104 (the flattened film 103), the light transmitting adhesive 110 may still flow over the protruding portions 106 into the electrode sections 107. Even if the height each of the protruding portions 106 is further increased to block the light transmitting adhesive against flowing over the protruding portions 106, the height each of the protruding portions 106 can be increased only to a height in the order of tens (10's) of micrometers, and it is therefore not possible to completely prevent the overflow of the light transmitting adhesive 110. Moreover, if the above problem is to be solved or restricted by increasing the height each of the protruding portions 106, it is difficult to take care of reducing the size of the optical device. Furthermore, an increased thickness of the light transmitting adhesive may result in decrease in the light collecting efficiency due to a reflection loss.

Furthermore, if there is any hollow portion such as a void between the semiconductor substrate 104 and the light transmitting board (glass plate) 102 in the conventional solid state imaging element, the refractive index is changed at the hollow portion, which affects receipt of light. Therefore, it is necessary to apply a larger amount of the light transmitting adhesive 110 on the light receiving section 101 so that the light transmitting adhesive 110 completely covers the light receiving section 101 and so that no hollow portion is formed. This makes it more likely that the light transmitting adhesive 110 flows into upper sides of the electrode sections 107 as the light transmitting adhesive 110 is spread out by the light transmitting board 102. Particularly, when reducing the size of the package including the semiconductor substrate 104, the light transmitting adhesive 110 is more likely to flow into lateral sides (outer lateral sides) and a back side of the semiconductor substrate 104. Therefore, solving such a problem is pressed in the pertinent art.

On the other hand, in case of another solid state imaging element proposed in Japanese Patent Publication No. 2009-135401, if a distance between adjacent two protruding portions 106 is set appropriately, bubbles can be removed from the space between the two protruding portions 106 even if the light transmitting adhesive 110 is applied in somewhat increased amount. And, since the light transmitting adhesive 110 can enter the space between the two protruding portions 106, it is possible to reduce an amount of the light transmitting adhesive 110 flowing out to a peripheral portion of the semiconductor substrate 104.

However, since the value of the appropriate distance between two adjacent protruding portions 106 varies depending on the amount of the light transmitting adhesive 110 to be applied, it is difficult to provide the two protruding portions 106 with an appropriate distance set therebetween. If the distance between the two protruding portions 106 is too small, the light transmitting adhesive 110 will not enter the space between the two protruding portions 106, so that it is not possible to prevent the light transmitting adhesive 110 from flowing over to the electrode sections 107. If the distance between the two protruding portions 106 is too large, on the other hand, the light transmitting adhesive 110 cannot be retained at the space between the two protruding portions 106 and flows out of the space. This problem seems to become evident as the solid state imaging element becomes miniaturized.

With an optical device according to the embodiments of the present invention, in the direct attachment structure, it is possible to effectively suppress the overflow of the light transmitting adhesive to the electrode section, and the lateral sides and the back side of the semiconductor substrate, and thus the optical device exhibits a reliable performance even if the optical device is reduced in size.

The above problem is solved by an optical device according to one aspect of the present invention, the optical device comprising: a semiconductor substrate having an element region formed on an upper side thereof, the element region including at least one of a light receiving region and a light emitting region; a light transmitting insulator film covering the element region and forming at least one recessed portion in a region thereof located outside the element region; at least one protruding portion provided on the light transmitting insulator film in a region outside the element region and inside the recessed portion; a light transmitting member covering the element region from above, the light transmitting member being provided on the protruding portion; and a light transmitting adhesive filled into a space provided between the light transmitting insulator film and the light transmitting member.

With the configuration as above, since the recessed portion is provided outside the protruding portion as viewed from the element region, even if the light transmitting adhesive overflows from the protruding portion when bonding the light transmitting member to the light transmitting insulator film, the overflow of the light transmitting adhesive can be stopped by the recessed portion. Therefore, it is possible to effectively suppress, by the recessed portion, the attachment of the light transmitting adhesive onto the edge regions, the lateral sides and the back side of the semiconductor substrate.

And, since the recessed portion is located outside the protruding portion, it is possible to prevent the light transmitting adhesive from flowing over to the edge regions or the like of the semiconductor substrate, while suppressing generation of the voids by applying the light transmitting adhesive in somewhat increased amount during the step of bonding the light transmitting member to the light transmitting insulator film. Therefore, it is possible to realize an optical device having high performance and reliability even if the optical device is reduced in size.

In many cases, an electrode, such as an electrode pad or a through electrode (through via), is arranged outside the element region for receiving/transmitting signals from/to the element region. With the optical device according to the one aspect of the present invention, it is possible to effectively prevent or reduce the light transmitting adhesive which flows over to such an electrode.

A method of manufacturing an optical device according to another aspect of the present invention, includes the steps of: preparing a semiconductor substrate having an element region formed on an upper side thereof, the element region including at least one of a light receiving region and a light emitting region, and forming a light transmitting insulator film on the semiconductor substrate for covering the element region; forming at least one recessed portion in a region of the light transmitting insulator film located outside the element region; after the step of forming the recessed portion, forming at least one protruding portion provided on a region of the light transmitting insulator film located outside the element region and inside the recessed portion; after the step of forming the protruding portion, applying a light transmitting adhesive in the liquid state on the light transmitting insulator film; and after the step of applying the light transmitting adhesive, placing a light transmitting member on the light transmitting insulator film to come into contact with the protruding portion and cover the element region from above, and then curing the light transmitting adhesive, thereby bonding the light transmitting member to the light transmitting insulator film via a layer of the light transmitting adhesive.

With the method as above, since the recessed portion is provided outside the protruding region, it is possible to effectively prevent the light transmitting adhesive from flowing over to the edge regions or the like of the semiconductor substrate during the step of bonding the light transmitting member to the light transmitting insulator film. Therefore, it is also possible to prevent the light transmitting adhesive from flowing over to the undesired regions during the step of bonding the light transmitting member to the light transmitting insulator film, while effectively suppressing generation of the voids, by applying the light transmitting adhesive in somewhat increased amount.

As discussed above, with the optical device and the method of manufacturing the same according to each one of the aspects of the present invention, it is possible to suppress adhesion of the layer of the light transmitting adhesive onto the edge region or the lateral sides of the semiconductor substrate, while suppressing generation of the voids. Thus, it is possible to reduce the size of the optical device and to improve the sensitivity of the optical device.

### BRIEF DESCRIPTION OF THE DRAWINGS

FIG. 1 is a perspective view showing a configuration of a solid state imaging device according to a first embodiment;

FIG. 2A is a top plan view showing a configuration of the solid state imaging element according to the first embodiment;

FIG. 2B is a view of the solid state imaging element in vertical section taken along the line II b-II b in FIG. 2A;

FIG. 3 is a perspective view showing a configuration of the solid state imaging device according to a second embodiment.

FIG. 4A is a top plan view showing a configuration of the solid state imaging element according to the second embodiment;

FIG. 4B is a view in vertical section of the solid state imaging element taken along the line IV b-IV b in FIG. 4A;

FIG. 4C is a view of the solid state imaging element in vertical section enlarging a portion of the solid state imaging element as shown in FIG. 4B in which portion a protruding portion and a recessed portion are formed;

FIG. 5 is a flow chart showing a method of manufacturing the solid state imaging device according to the second embodiment.

FIGS. 6A through 6E are views in vertical section each showing a method of manufacturing the solid state imaging device according to the second embodiment.

FIG. 7A is a view in vertical section enlarging a portion of the solid state imaging element and showing a protruding portion and a recessed portion formed in the solid state imaging element according to a first modified example of the second embodiment;

FIG. 7B is a view in vertical section enlarging a portion of the solid state imaging element and showing a protruding portion and a recessed portion formed in the solid state imaging element according to a second modified example of the second embodiment;

FIG. 8A is a top plan view showing a configuration of the solid state imaging element according to a third embodiment;

FIG. 8B is a view of the solid state imaging element in vertical section taken along the line VIII b-VIII b in FIG. 8A;

FIG. 9A is a top plan view showing a configuration of the solid state imaging element according to a first modified example of the third embodiment;

FIG. 9B is a top plan view showing a configuration of the solid state imaging element according to a second modified example of the third embodiment;

FIG. 10A is a top plan view showing a configuration of a light emitting diode (LED) according to a fourth embodiment;

FIG. 10B is a view in vertical section taken along the line X b-X b in FIG. 10A;

FIG. 11 is a view in vertical section showing a configuration of a solid state imaging element according to a fifth embodiment; and

FIG. 12 is a view in vertical section showing a configuration of a conventional solid state imaging element having a direct attachment structure.

### DETAILED DESCRIPTION

Embodiments according to the present invention will be described hereinafter with reference to the accompanying drawings.

### First Embodiment

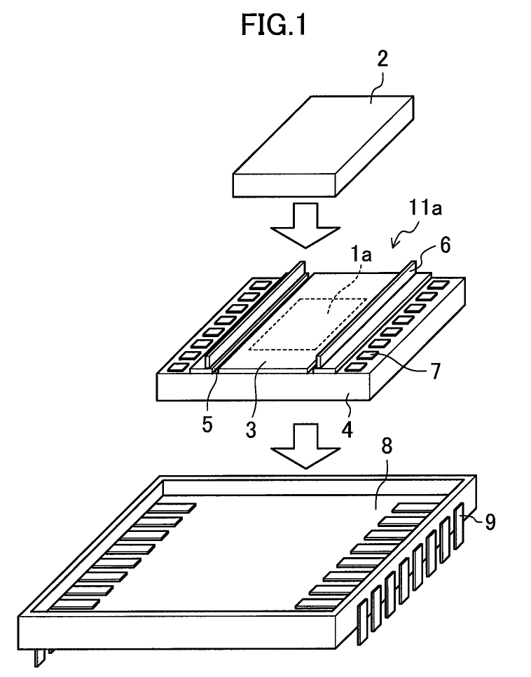

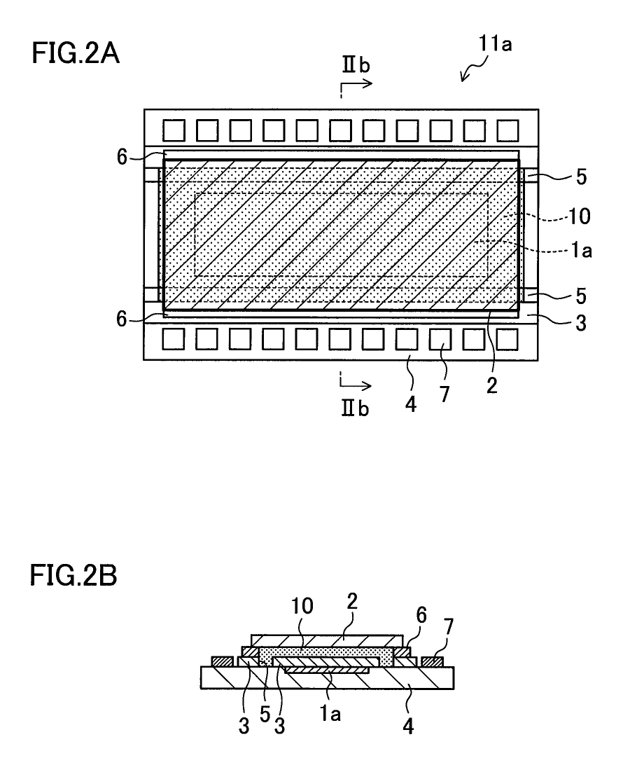

In a first embodiment of the present invention, a solid state imaging device will be described by taking it as an example of an optical device. FIG. 1 is a perspective view showing a configuration of a solid state imaging device according to the first embodiment. FIG. 2A is a top plan view showing a configuration of the solid state imaging element according to the first embodiment; and FIG. 2B is a view of the solid state imaging element in vertical section taken along the line II b-II b in FIG. 2A.

As shown in FIG. 1 and FIGS. 2A and 2B, the solid state imaging device according to the present embodiment includes a solid state imaging element 11a. The solid state imaging element 11a includes: a semiconductor substrate 4 having a light receiving region la acting as an element region formed thereon; a plurality of electrode pads 7 formed along the edge regions of the semiconductor substrate 4; recessed portions (groove portions) 5 extending between the light receiving region 1a and the electrode pads 7 as viewed from above; a light transmitting insulator film (light transmitting flattened film) 3 formed on the semiconductor substrate 4 so as to cover the light receiving region 1a from above; protruding portions (blocking portions) 6 extending on the light transmitting insulator film 3 and between the recessed portions 5 and the electrode pads 7 as viewed from above; a light transmitting adhesive 10 provided on the semiconductor substrate 4 and the light transmitting insulator film 3 so as to be filled in the recessed portions 5; and a light transmitting member 2 bonded on the light transmitting adhesive 10 and protruding portions 6 so as to cover the light receiving region 1a as viewed from above.

In the present specification, the term “element region” refers to a light receiving region in case of a light receiving device such as a solid state imaging device, a light emitting region in case of a light emitting device such as a light emitting diode (LED) to be described later, and a light receiving/emitting region in case of an optical device having a light receiving element and a light emitting element juxtaposed with each other.

In the solid state imaging device according to the present embodiment, as shown in FIG. 1, the solid state imaging element 11a with the light transmitting member 2 bonded thereto is placed on a package substrate 8 having a plurality of leads 9 provided therewith.

As shown in FIG. 2B, the solid state imaging device according to the present embodiment includes the light transmitting insulator film 3 with the recessed portions 5 formed therein, and the protruding portions 6 formed on the light transmitting insulator film 3. The recessed portions 5 are filled with the light transmitting adhesive 10. In FIG. 2A, a range of extending the light transmitting adhesive 10 is shown in a polka dot pattern.

With this configuration, since the recessed portions 5 are each formed in a region between the light receiving region 1a (element region) and the electrode pads 7 as viewed from above, a portion of the light transmitting adhesive 10 overflowing to a peripheral portion of the light transmitting member 2 runs into the recessed portions 5 when the light transmitting member 2 is directly bonded to the light transmitting insulator film 3. Therefore, it is possible to prevent or reduce a flow of the light transmitting adhesive 10 over the electrode pads 7. Furthermore, since the solid state imaging device according to the present embodiment includes the protruding portions 6 extending between the recessed portions 5 and the electrode pads 7 as viewed from above, the flow of the light transmitting adhesive 10 can be blocked by the protruding portions 6 even when the light transmitting adhesive 10 should flow further outside the recessed portions 5. As a result, according to the present configuration, it is possible to realize a solid state imaging device having a direct attachment structure with a reduced size, high sensitivity and desirable performance, while suppressing adhesion of the light transmitting adhesive 10 onto the electrode pads 7 in a reliable manner.

In furtherance to the above, since the recessed portions 5 and the protruding portions 6 are arranged in combination, the size of the solid state imaging element can be reduced compared with the configuration with a further (second) protruding portion being provided outside the (first) protruding portion 6. As described above, increasing the height each of the protruding portions 6 is limitative, and increasing the width each of the protruding portions 6 is not so effective to enhance the suppression of the overflow of the light transmitting adhesive 10. On the other hand, the recessed portions 5 formed in the light transmitting insulator film 3 can increase an amount of retaining the light transmitting adhesive 10 by increasing the width each of the recessed portions 5. Therefore, with the provision of the recessed portions 5 and the protruding portions 6 in combination, it is possible to optimize a configuration of the solid state imaging element depending on the applied amount of the light transmitting adhesive and so on, resulting in reducing the size of the solid state imaging device.

### Second Embodiment

During the steps of manufacturing the solid state imaging element according to the first embodiment as shown in FIGS. 2A and 2B, the light transmitting adhesive 10 is applied onto the semiconductor substrate 4 so as to have the semiconductor substrate 4 bonded to the light transmitting member 2 formed of a glass plate or the like. With the solid state imaging element according to the first embodiment, the protruding portions 6 each in the form of a wall are provided between the plurality of electrode pads 7 and the light receiving region 1a (element region), and the recessed portions 5 are provided between the protruding portions 6 and the light receiving region 1a, whereby during the bonding step, it is possible to effectively prevent the light transmitting adhesive 10 from flowing over to the electrode pads 7.

As the solid state imaging device is progressively miniaturized, however, the amount of the light transmitting adhesive 10 necessary during the bonding step is decreased as described above, and inconsistent variation of the applied amount of the light transmitting adhesive 10 will become more influencing on the performance of the solid state imaging device. After the inventors of the present application further researched and developed in this regard, they found as follow. Namely, by arranging the recessed portions 5 outside the protruding portions 6, the light transmitting adhesive 10 becomes less likely to flow over to the electrode pads 7 even when the applied amount of the light transmitting adhesive 10 is increased during the bonding step of the light transmitting member 2. Besides, even if the applied amount of the light transmitting adhesive 10 is small, it becomes less likely to generate a void at a bonding portion between the light transmitting member 2 and the protruding portions 6 or the like. Hereinafter, a solid state imaging device having such a configuration as above will be described in more detail.

### (Configuration of the Solid State Imaging Device According to the Second Embodiment)

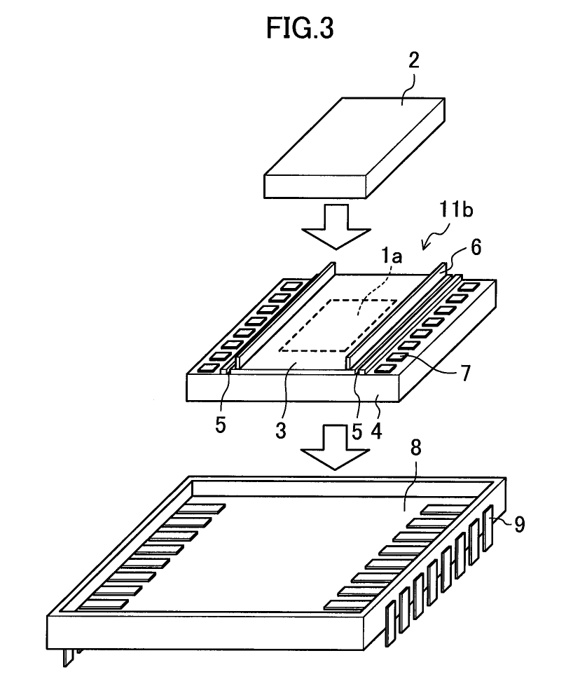

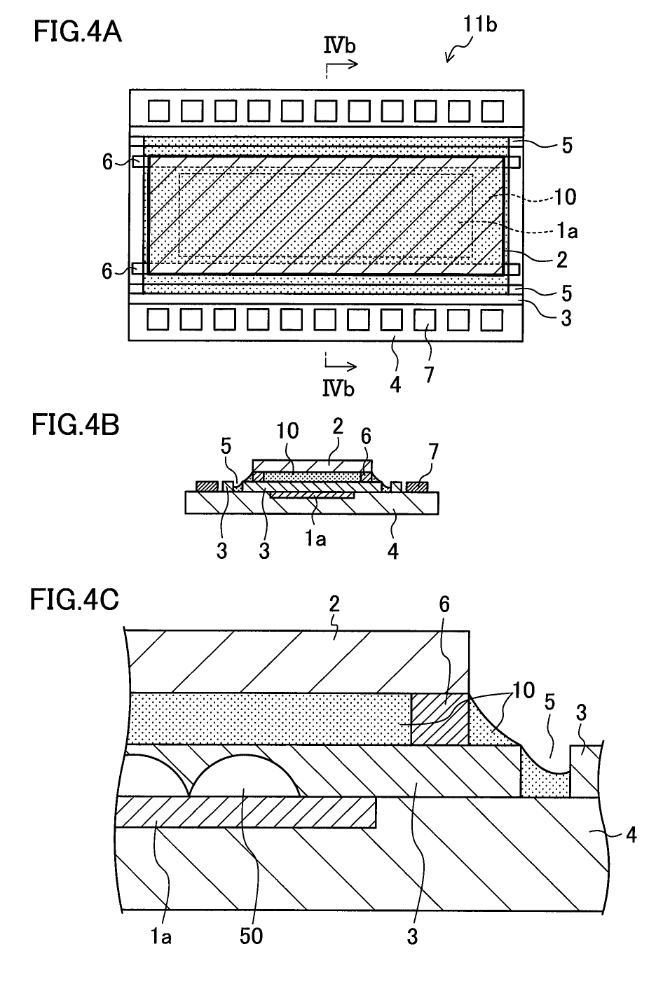

FIG. 3 is a perspective view showing a configuration of the solid state imaging device according to a second embodiment. FIG. 4A is a top plan view showing a configuration of the solid state imaging element according to the present embodiment, and FIG. 4B is a view of the solid state imaging element in vertical section taken along the line IV b-IV b in FIG. 4A. And, FIG. 4C is a view of the solid state imaging element in vertical section enlarging a portion of the solid state imaging element as shown in FIG. 4B in which portion a protruding portion 6 and a recessed portion 5 are formed.

As shown in FIG. 3, in the solid state imaging device according to the present embodiment, a solid state imaging element 11b having a light transmitting member 2 bonded thereto is installed on a package substrate 8 having a plurality of leads 9 extending therethrough.

As shown in FIGS. 4A through 4C, the solid state imaging element 11b according to the present embodiment includes: a semiconductor substrate 4 having a light receiving region 1a acting as an element region formed on an upper side thereof; a plurality of electrode pads 7 each formed on the upper side of the semiconductor substrate 4 in a region located outside the light receiving region 1a; a light transmitting insulator film (light transmitting flattened film) 3 formed on the semiconductor substrate 4 so as to cover the light receiving region 1a, the light transmitting insulator film 3 having recessed portions (groove portions) 5 extending therein between the light receiving region 1a (element region) and the electrode pads 7 as viewed from above (that is, at positions outside the light receiving region 1a and inside the electrode pads 7); protruding portions (blocking portions) 6 extending on the light transmitting insulator film 3 between the recessed portions 5 and the light receiving region 1a as viewed from above; a light transmitting member 2 provided on the protruding portions 6 so as to cover the light receiving region 1a from above; and a light transmitting adhesive 10 filled into the space between the light transmitting member 2 and the light transmitting insulator film 3.

The light transmitting member 2 is formed of glass having a shape of a plate, for example. The height each of the protruding portions 6 may be no more than tens (10's) of micrometers for reducing the thickness of the solid state imaging device, and in the order of 8 to 10 micrometers, for example.

And, as shown in FIG. 4C, it is preferred to provide light collecting lenses 50, one for each one pixel, on the light receiving region 1a. The light transmitting insulator film 3 is provided so as to embed the light collecting lenses 50 therewithin. The thickness of the light transmitting insulator film 3 (i.e. the depth each of the recessed portions 5) may be in the order of 8 to 10 micrometers, for example. The width each of the recessed portions 5 may be in the order of 100 micrometers, for example.

In the embodiment as shown in FIGS. 4A through 4C, each of the protruding portions 6 is in the form of a wall, and extends substantially parallel to a side of the semiconductor substrate 4 where the electrode pads 7 are arranged. The recessed portions 5, which are located outside the protruding portions 6 as viewed from the light receiving region 1a, extend parallel to the protruding portions 6, for example. In other words, the recessed portions 5 and the protruding portions 6 are formed along a direction arranging the plurality of the electrode pads 7. On the light transmitting insulator film 3, a position of an inner lateral wall (one lateral side adjacent the light receiving region 1a) of each recessed portion 5 may be substantially aligned with a position of an outer lateral side (one lateral side remote from the light receiving region 1a) of each protruding portion 6. As an alternative, the position of the outer lateral side of the protruding portion 6 may be located inside the position of the inner lateral wall of the recessed portion 5.

Incidentally, existence or absence of the light transmitting adhesive 10 within the recessed portion 5 depends on the amount of the light transmitting adhesive 10 applied during the step of bonding the light transmitting member 2 to the light transmitting insulator film 3.

In whichever case, with the solid state imaging device according to the present embodiment, the protruding portions 6 are formed outside the light receiving region 1a and inside the electrode pads 7 as viewed from above, and the recessed portions 5 are formed between the protruding portions 6 and the electrode pads 7. Thus, even if the light transmitting adhesive 10 overflows from the protruding portions 6 toward the electrode pads 7 when the light transmitting member 2 is directly bonded to the light transmitting insulator film 3, the overflow of the light transmitting adhesive 10 can be stopped within the recessed portions 5 in a reliable manner.

In these manners, the solid state imaging device according to the present embodiment invites a synergy effect, that is, a combination of an effect of blocking the light transmitting adhesive 10 by the protruding portions 6 and a further effect of preventing the overflow of the light transmitting adhesive 10 by the recessed portions 5. Thus, even if the applied amount of the light transmitting adhesive 10 is somewhat increased with taking account of inconsistent variation of the applied amount of the light transmitting adhesive 10, the light transmitting adhesive 10 will not flow over to the electrode pads 7. Thus, with the solid state imaging device according to the present embodiment, it is possible to effectively prevent the light transmitting adhesive 10 from being attached to the electrode pads 7, while suppressing generation of the voids even if the solid state imaging device is reduced in its size. With the configuration as described above, therefore, it is possible to realize a solid state imaging device having a high sensitivity and reliability.

With the solid state imaging device according to the first embodiment, if the applied amount of the light transmitting adhesive 10 is too small due to inconsistent variation of the applied amount of the light transmitting adhesive 10, it is slightly likely that the voids will be generated at the corner portions where the protruding portions 6 and the light transmitting member 2 come into contact within each other, since the light transmitting adhesive 10 is embedded with the recessed portion 5. With the solid state imaging device according to the present embodiment, on the other hand, since the recessed portions 5 are located outside the protruding portions 6, it is possible to stop the light transmitting adhesive 10 against overflowing from the protruding portion 6 in more reliable manner by the recessed portion 5, while effectively preventing generation of the voids by applying the light transmitting adhesive 10 in somewhat increased amount.

In the embodiment as shown in FIG. 4A, the protruding portion 6 is illustrated as having a rectangular shape as viewed from above, but it is to be noted that the shape of the protruding portion 6 as viewed from above is not limited thereto, which will be described later. And, with the solid state imaging device according to the embodiment as described above, only one protruding portion 6 in the form of a wall is provided for the plurality of electrode pads 7 arranged in a row extending along one side of the semiconductor substrate 4. Instead, a plurality of split and shorter protruding portions 6 may be provided as will be described later.

And, a shape of the protruding portion 6 in vertical section is illustrated in FIG. 4B as the shape has four sides with each adjacent pair thereof being interconnected at right angles, but the shape of the vertical section is not limited thereto. Instead, the protruding portion 6 may have another shape in vertical section, such as a trapezoidal shape, as will be described later also.

In furtherance thereto, the dimensions of the recessed portion 5 such as its width, depth or the like is not limited to the values described above. The values of the respective dimensions can be determined appropriately by taking account of physical properties such as the applied amount, the viscosity or the like of the light transmitting adhesive 10 so as to secure the capacity of the recessed portion 5 to be sufficient to prevent the light transmitting adhesive 10 from overflowing to the electrode pads 7. And, the recessed portion 5 does not necessarily have to extend through the light transmitting insulator film 3.

In still furtherance thereto, with the solid state imaging device according to the present embodiment, the electrode pads 7 are arranged along the edge regions of the respective, two opposite sides of the semiconductor substrate 4, but this is not limitative. It is sufficient if only each of the protruding portions 6 and the recessed portions 5 is provided between the electrode pads 7 and the light receiving region 1a. Therefore, a plurality of the electrode pads 7 may be further arranged along another side(s) of the semiconductor substrate 4. In whichever case, when the protruding portions 6 are provided along the opposite sides of the light receiving region 1a, the upper and lower sides of the light transmitting member 2 may be placed in parallel to a circuit forming surface of the semiconductor substrate 4 with high precision.

In still yet furtherance thereto, with the solid state imaging device according to the present embodiment, the light transmitting insulator film 3 is provided, with the recessed portions 5 being formed therein. However, it is not necessary for the film 3 to have an insulating property, so long as the film 3 has a light transmitting property.

Finally, with the solid state imaging device according to the present embodiment, the thickness of the light transmitting insulator film 3 may be appropriately adjusted so as to improve an incident index of light which is incident to the light receiving region 1a.

### (Method of Manufacturing the Solid State Imaging Device According to the Second Embodiment)

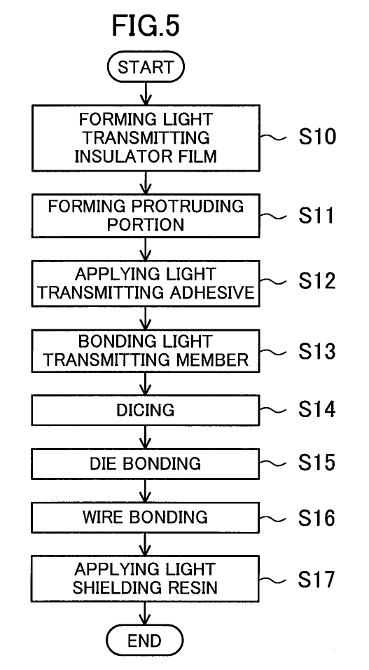

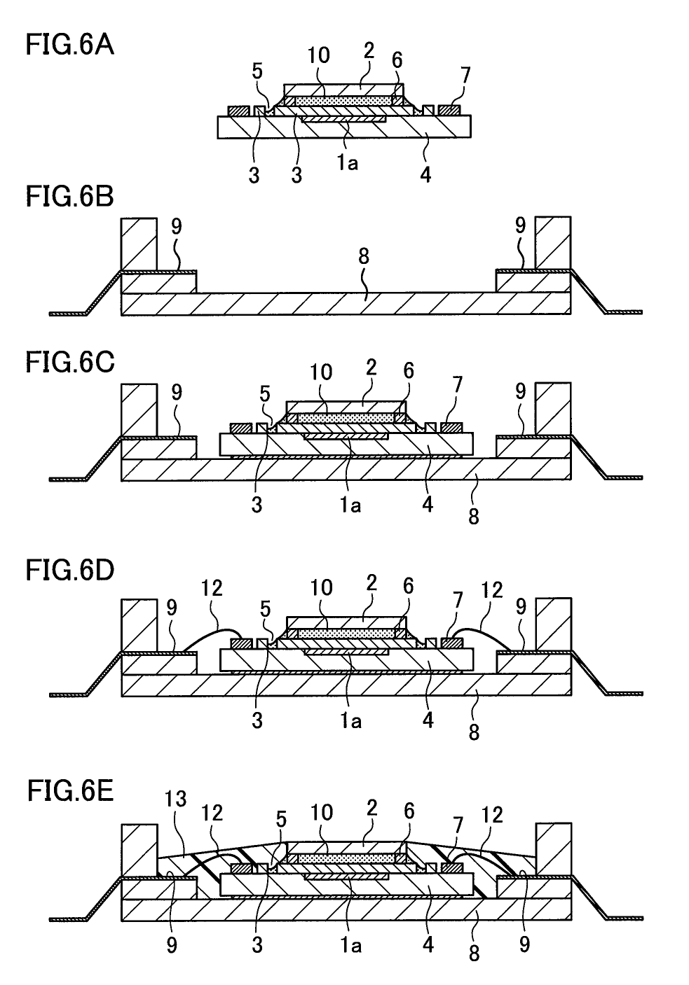

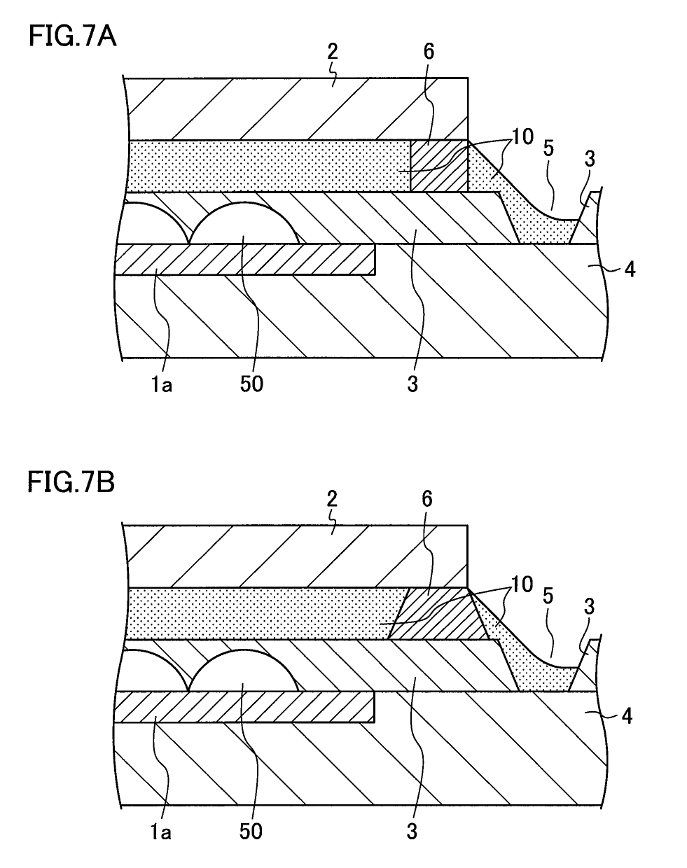

FIG. 5 is a flow chart showing a method of manufacturing the solid state imaging device according to the present embodiment. FIGS. 6A through 6E are views in vertical section each showing a method of manufacturing the solid state imaging device according to the present embodiment.

As shown in FIG. 5, with the method of manufacturing the solid state imaging device according to the present embodiment, first, during the step S10, the light receiving region 1a and the plurality of the electrode pads 7 are formed on the semiconductor substrate 4 in the form of a wafer. The semiconductor substrate 4 has chip regions partitioned thereon, each of which regions will form a solid state imaging element 11b during later steps, and the light receiving region 1a and the plurality of the electrode pads 7 are provided on each of the chip regions. Subsequently, the light transmitting insulator film 3, having a thickness thereof in the order of 8 to 10 micrometers, for example and being formed of an organic material or the like, is formed on the semiconductor substrate 4 in each of the chip regions so as to cover the light receiving region 1a.

Then, a portion of the light transmitting insulator film 3 located between the electrode pads 7 and the light receiving region 1a as viewed from above is selectively removed, thereby forming the recessed potions 5 in the light transmitting insulator film 3. In more particular about how the recessed portions 5 are formed, after the light transmitting insulator film 3 is formed on the semiconductor substrate 4, a resist material is accumulated on the light transmitting insulator film 3. Then, a portion of the light transmitting insulator film 3 for forming each of the recessed portions 5 is selectively removed by using an etching method with the resist material acting as a mask.

Then, during the step S11, the protruding portions 6, each formed of a photosensitive material or the like, are formed on the regions of the light transmitting insulator film 3, with each region being located between the recessed portion 5 associated therewith and the light receiving region 1a as viewed from above. In more particular about how the protruding portions 6 are formed, after the photosensitive material formed of e.g. acrylates is applied onto the light transmitting insulator film 3, a mask is formed on the photosensitive material. Subsequently, a portion of the photosensitive material other than the regions for forming the protruding portions 6 are selectively removed by using, together with the mask, a photography method and an etching method, thereby forming the protruding portions 6.

Then, during the step S12, the light transmitting adhesive 10 in a liquid state is applied onto the light transmitting insulator film 3. In doing so, it is preferable that the light transmitting adhesive 10 is applied in an amount a little larger than the amount necessary to fill the space between the light transmitting member 2 and the light transmitting insulator film 3 in order to prevent or reduce generation of the voids in that space. The light transmitting adhesive 10 may be an acrylic based adhesive having a curing property with respect to an ultraviolet (UV) ray, for example.

Then, during the step S13, after placing the light transmitting member 2 on the semiconductor substrate 4 so as to cover the light receiving region 1a from above, the light transmitting adhesive 10 is cured by irradiating the UV ray or the like. Whereby, the light transmitting member 2 is bonded to the light transmitting insulator film 3 by the light transmitting adhesive 10.

Then, during the step S14, as shown in FIG. 6A, the plurality of the solid state imaging elements 11b obtained during the step S13 are separated into pieces by a dicing or die cutting method.

Then, during the step S15, as shown in FIG. 6B, a package substrate 8, having a plurality of leads 9 provided therewith, is prepared first. Then, as shown in FIG. 6C, each of the separated solid state imaging element 11b is mounted on the package substrate 8 by die bonding.

Subsequently, during the step S16, as shown in FIG. 6D, the plurality of leads 9 are connected by the wires 12 to the respective electrode pads 7 provided on the solid state imaging element 11b, by using a wire bonding method. Then, during the step S17, as shown in FIG. 6E, a light shielding resin material 13 is applied onto a region of the semiconductor substrate 4 other than the upper side of the light transmitting member 2, thereby packaging the solid state imaging element 11b. In these manners, the solid state imaging device according to the present embodiment can be manufactured.

According to the method of manufacturing the solid state imaging device according to the present embodiment as described above, during the step S10, the light transmitting insulator film 3 having the recessed potions 5 formed therein is provided. Then, during the step S11, the protruding portions 6 are formed to each be located inside the recessed portion 5 associated therewith (i.e. closer to the light receiving region 1a than the recessed portion 5).

With the present method, each of the recessed portion 5 is formed in a region of the light transmitting insulator film 3 located outside the protruding portion 6 associated therewith. Whereby, during the steps S12 and S13, the light transmitting adhesive 10 is blocked by the protruding portion 6 against flowing. In furtherance thereto, even if the light transmitting adhesive 10 overflows outside the protruding portion 6 when the light transmitting adhesive 10 is applied in an increased amount, the overflow of the light transmitting adhesive 10 can be blocked within the recessed portion 5.

Thus, it is possible to prevent the light transmitting adhesive 10 from flowing over to the electrode pads 7. As a result, during the step S17, for example, when the electrode pads 7 are connected by the wires to the plurality of the respective leads 9 by using the wire bonding method, it is possible to suppress occurrence of the trouble of a connection failure or the like, which allows to smoothly perform the wire bonding method. As a result, when using the method of manufacturing the optical device according to the present embodiment, in the direct attachment structure, it is possible to prevent the light transmitting adhesive 10 from being attached to the electrode pads 7 in a more reliable manner, whereby it is possible to manufacture the solid state imaging device with its size being reduced but exhibiting high sensitivity and satisfactory performance. In furtherance thereto, since the generation of the voids can be effectively suppressed or reduced by applying the light transmitting adhesive 10 in somewhat increased amount, the solid state imaging device manufactured according to the steps described above can obtain a better image with the light transmitting proportion of the incident light being made uniform in the light receiving region 1a.

In furtherance thereto, with the method of manufacturing the solid state imaging device according to the present embodiment, it is possible to obtain the solid state imaging device having the direct attachment structure in a package which is sealed by the plastic material or the like, so that it is possible to effectively prevent entry of dust into the light receiving region 1a and other troubles from occurring during the manufacturing steps. Therefore, when using the method of manufacturing the solid state imaging device according to the present embodiment, it is possible to obtain a semiconductor device with its size reduced and having a high reliability.

### First Modified Example of the Second Embodiment

FIG. 7A is a view in vertical section enlarging a portion of a solid state imaging element having a protruding portion and a recessed portion formed therein according to a first modified example of the second embodiment.

Compared with the solid state imaging element according to the second embodiment as shown in FIGS. 4A through C, in the solid state imaging element according to the present modified example, the recessed portion 5 has a profile of a wall for forming an inclined side in order to reduce a width of the recessed portion 5 as the recessed portion 5 extends downward. The configuration of the solid state imaging element other than the shape of the recessed portion 5 is common with the solid state imaging element according to the foregoing second embodiment, and thus description of the common features of the configuration will not be described again.

Since the wall of the recessed portion 5 is angled as shown in FIG. 7A, compared with the configuration in which the wall of the recessed portion 5 is oriented at right angles with respect to the upper side (circuit forming surface) of the semiconductor circuit 4, when bonding the light transmitting member 2 to the light transmitting insulator film 3, it is possible to guide the light transmitting adhesive 10 overflowing from the protruding portion 6 to the recessed portion 5 more quickly. In addition, since the excessive light transmitting adhesive 10 is captured within the recessed portion 5, it is possible to effectively prevent the overflow of the light transmitting adhesive 10 to the electrode pads 7, while applying the light transmitting adhesive 10 in somewhat increased amount in order to suppress the generation of the voids. It is to be noted that such an effect can be invited so long as at least one wall of the recessed portion 5 closer to the light receiving region 1a is inclined to reduce the width of the recessed portion 5 as the recessed portion 5 extends downward to a bottom thereof.

It is to be noted also that such a tapered vertical section of the recessed portion 5 can be formed easily during the step S10 as shown in FIG. 5, by adjusting the etching conditions of the light transmitting insulator film 3 and so on.

### Second Modified Example of the Second Embodiment

FIG. 7B is a view in vertical section enlarging a portion of a solid state imaging element having a protruding portion and a recessed portion formed therein according to a second modified example of the second embodiment.

Compared with the solid state imaging element according to the first modified example as shown in FIG. 7A, in the solid state imaging element according to the present modified example, the protruding portion 6 is formed to have a tapered shape in vertical section extending through the light receiving region 1a and the recessed portion 5. In other words, as shown in FIG. 7B, the protruding portion 6 is formed to have a trapezoidal profile in vertical section extending through the light receiving region 1a and the recessed portion 5.

Since the lateral sides of the protruding portion 6 are inclined, compared with the solid state imaging element according to the first modified example, when bonding the light transmitting member 2 to the light transmitting insulator film 3, it is possible to guide the light transmitting adhesive 10 after overflowing from the protruding portion 6 toward into the recessed portion 5 more quickly. In particular, since the inner side of the protruding portion 6 (the side oriented in opposition to the light receiving region 1a) is inclined, it is possible to effectively prevent generation of the voids at the corner portions where the light transmitting member 2 and the protruding portions 6 come into contact with each other.

Such a protruding portion 6 can be formed easily during the step S11 as shown in FIG. 5, by appropriately adjusting the photography conditions and the etching conditions of the photosensitive material and so on.

### Third Embodiment

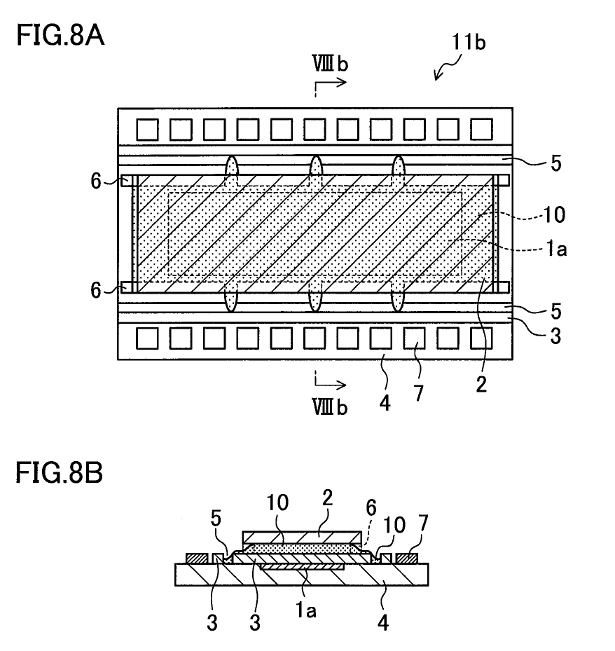

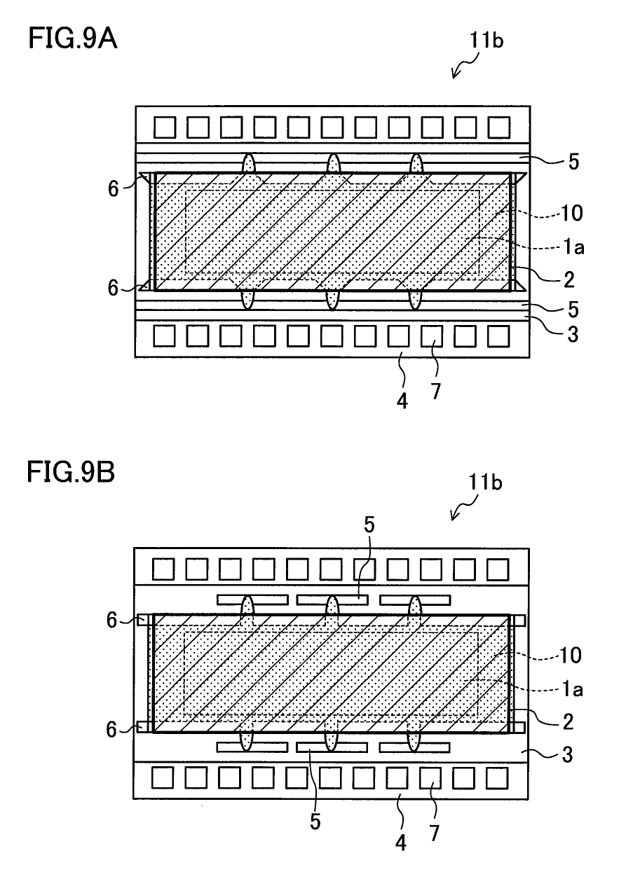

FIG. 8A is a top plan view showing a configuration of the solid state imaging element according to a third embodiment, and FIG. 8B is a view in vertical section taken along the line VIII b-VIII b in FIG. 8A. In fact, the protruding portion 6 cannot be seen in the vertical section as shown in FIG. 8B, but the region forming each of the protruding sections 6 is shown in broken lines in order to understand it easily, assuming that the vertical section could be seen through to the protruding portions 6.

With the solid state imaging element 11b according to the present embodiment, a plurality of protruding portions 6 are provided for each one side of the semiconductor substrate 4, and two protruding portions 6 adjacent to each other are provided with a predetermined distance in between. Each of the protruding portions 6 has a four-sided shape (rectangular shape), for example, as viewed from above. Each of the protruding portions 6 has a vertical section thereof in a four-sided shape, for example, taken along through the light receiving region 1a and the electrode pads. The configuration of the solid state imaging element other than the above is common with the solid state imaging element according to the foregoing second embodiment, and thus description of the common features of the configuration will not be described again.

As shown in FIG. 8A, the plurality of the split, protruding portions 6 are provided each with a predetermined distance in between. Thus, during the bonding step of the light transmitting member 2, the light transmitting adhesive 10 in the liquid state enters the space in between the two adjacent protruding portions 6, and is retained therein under the surface tension. Thus, compared with the solid state imaging element according to the second embodiment, it is possible to still more effectively prevent the excessive amount of the light transmitting adhesive 10 from flowing over to the electrode pads 7.

The distance between the two, adjacent protruding portions 6 may be appropriately adjusted by taking account of the physical properties such as the applied amount, the viscosity or the like of the light transmitting adhesive 10. However, as the solid state imaging element is the more miniaturized, the more difficult it becomes to set the appropriate distance between the two, adjacent protruding portions 6, and the more difficult it becomes also to machine the protruding portions 6 as they are designed.

However, with the solid state imaging element 11b according to the present embodiment, since the recessed portions 5 are provided outside the protruding portions 6, it is possible to effectively prevent the light transmitting adhesive 10 from flowing over to the electrode pads 7, even if the distance between the adjacent protruding portions 6 should be too large to sufficiently retain the light transmitting adhesive 10 therein. Even if the distance between the adjacent protruding portions 6 should be too small, on the other hand, the distance is still effective to prevent the light transmitting adhesive 10 from flow over onto the electrode pads 7, in a similar manner to the solid state imaging element according to the second embodiment. Thus, it is possible to enhance the reliability of the solid state imaging element and the solid state imaging device having the same, compared with the conventional art.

In furtherance thereto, with the solid state imaging element 11b according to the present embodiment, bubbles can be removed from the space between the two protruding portions 6 when the light transmitting member 2 is bonded to the light transmitting insulator film 3. This suppresses generation of the voids.

As described above, with the solid state imaging element 11b according to the present embodiment, it is possible to suppress occurrence of the connection failure or the like at the electrode pads 7 even if the distance between the two adjacent protruding portions 6 is not preset appropriately, and also suppress or reduce generation of the voids. This ensures high reliability and performance of the solid state imaging element 11b, even if the solid state imaging element 11b is miniaturized.

It is to be noted that a shape in vertical section of the recessed portion 6 and a distance between the two adjacent recessed portions 6 are not limited to the examples as shown in FIGS. 8A and B as will be described later.

### First Modified Example of the Third Embodiment

FIG. 9A is a top plan view showing a configuration of a solid state imaging element according to a first modified example of the third embodiment.

As shown in FIG. 9A, in the solid state imaging element 11b according to the present modified example, each of the protruding portions 6 has a substantially trapezoidal shape as viewed from above, in which shape a side facing the light receiving region 1a is a short side of the trapezoidal, and a side facing the electrode pads 7 is a long side of the trapezoidal.

With this configuration, since a distance between the two, adjacent protruding portions 6 becomes smaller as it extends from the light receiving region 1a toward the electrode pads 7 and the recessed portion 5, it is possible to cause the excessive, light transmitting adhesive 10 to smoothly flow outside the protruding portions 6 when the light transmitting member 2 is bonded. And, since the light transmitting adhesive 10 after overflowing from the protruding portions 6 is reserved in the recessed portion 5, the light transmitting adhesive 10 will not flow onto the electrode pads 7. Thus, it is possible to suppress occurrence of the connection failure at the electrode pads 7, even if the light transmitting adhesive 10 is applied in somewhat increased amount in order to suppress generation of the voids.

### Second Modified Example of the Third Embodiment

FIG. 9B is a top plan view showing a configuration of a solid state imaging element according to a second modified example of the third embodiment.

In the solid state imaging element 11b according to the present modified example, compared with the solid state imaging element according to the foregoing third embodiment, one recessed portion 5 having a small width is split into a plurality of shorter pieces. The number of the split pieces of the recessed portions 5 arranged on one side of the semiconductor substrate 4 can be determined as desired, but it is preferred that at least one recessed portion 5 is provided at a position close to the space between the two adjacent protruding portions 6.

With this configuration, too, it is possible to suppress the overflow of the light transmitting adhesive 10 over to the electrode pads 7 by retaining, within the recessed portions 5, the light transmitting adhesive 10 having flown out of the space between the adjacent protruding portions 6, while suppressing generation of the voids by applying the light transmitting adhesive 10 in somewhat increased amount.

### Fourth Embodiment

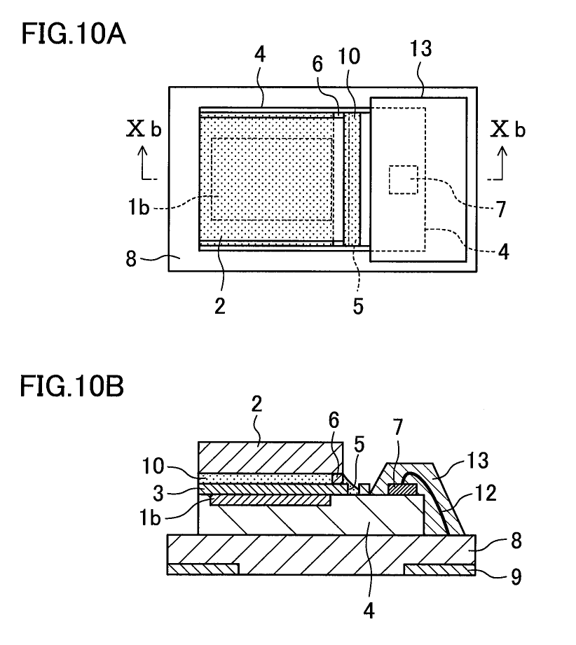

In a fourth embodiment of the present invention, a light emitting diode (LED) will be described by taking it as an example of an optical device. FIG. 10A is a top plan view showing a configuration of the LED according to the present embodiment, and FIG. 10B is a view in vertical section taken along the line X b-X b in FIG. 10A.

As shown in FIGS. 10A and 10B, the LED according to the present embodiment includes: a semiconductor substrate 4 having a light emitting region 1b formed on an upper side thereof; an electrode pad 7 formed in a region of the upper side of the semiconductor substrate 4 located outside the light emitting region 1b; a light transmitting insulator film 3 formed on the semiconductor substrate 4 so as to cover the light emitting region 1b (element region) from above, the light transmitting insulator film 3 having a recessed portion 5 extending between the light emitting region 1b (element region) and the electrode pad 7 as viewed from above; a protruding portion 6 extending on the light transmitting insulator film 3 and between the recessed portions 5 and the light emitting region 1b as viewed from above; a light transmitting member 2 provided on the protruding portion 6 so as to cover the light emitting region 1b from above; and a light transmitting adhesive 10 filled in a distance between the light transmitting member 2 and the light transmitting insulator film 3.

In furtherance thereto, as shown in FIGS. 10A and 10B, the LED according to the present embodiment includes a package substrate 8 having a plurality of leads 9 provided thereto, and the semiconductor substrate 4 with the light transmitting member 2 bonded thereto will be placed on the package substrate 8. The electrode pad 7 and a wire 12 connected to the electrode pad 7 are sealed by a light shielding resin material 13.

In FIG. 10B, the light transmitting adhesive 10 is present in the recessed portion 5. However, the light transmitting adhesive 10 may be absent in the recessed portion 5, depending on the amount of the light transmitting adhesive 10 applied during the bonding step of the light transmitting member 2.

With the configuration as described above, when the light transmitting member 2 is directly bonded on the light transmitting insulator film 3, the light transmitting adhesive 10 applied above the light emitting region 1b is blocked by the protruding portion 6. When the applied amount of the light transmitting adhesive 10 is too large, the light transmitting adhesive 10 will overflow from the protruding portion 6. In such a case, too, since the recessed portion 5 is formed outside the protruding portion 6, the light transmitting adhesive 10 having flown over from the protruding portion 6 will be retained within the recessed portion 5. This effectively prevents the light transmitting adhesive 10 from flowing over to the electrode pad 7 arranged outside the recessed portion 5. As a result, with the optical device according to the present embodiment, it is possible to effectively prevent the light transmitting adhesive 10 from being attached to the electrode pad 7, and to realize an optical device which is miniaturized and has a high performance.

It is to be noted that the examples of the optical device according to the present invention is not limited to the solid state imaging device described in the first through third embodiments or the LED described in the fourth embodiment. Similar effects to the optical devices according to the embodiments described above can be obtained in case also of another optical device having an image sensor (solid state imaging element) such as a charge coupled device (CCD) and a complementary metal oxide semiconductor (CMOS) or the like; and a light receiving element such as a photo diode, a photo transistor and a photo integrated circuit (IC) or the like. In furtherance thereto, the configuration of the protruding portion and the recessed portion as described above is applicable to a light receiving/emitting device having the light receiving element and the light emitting element juxtaposed to each other.

It is to be noted also that, when the configuration as described above is applied to a solid state imaging device as those in the first through third embodiments according to the present invention, this configuration is useful to enhance performance of a camera module of a digital camera, a camera module of a cellular phone, and a camera mounted on a vehicle, for example.

In still furtherance thereto, the configuration described above is applicable also to an optical device having a light emitting element such as an LED, a semiconductor laser, etc. In this application, the LED has its utility to a light emitting display of a cellular phone, and an illumination module, for example. The semiconductor laser preferably has its utility to a driver device each for a blu-ray disc (BD), a digital versatile disc (DVD), a compact disc read only memory (CD-ROM) and so on.

### Fifth Embodiment

A fifth embodiment of the present invention will be described hereinafter, in which embodiment a through electrode or a through via is provided instead of the electrode pads in the solid state imaging element according to the foregoing embodiments described above.

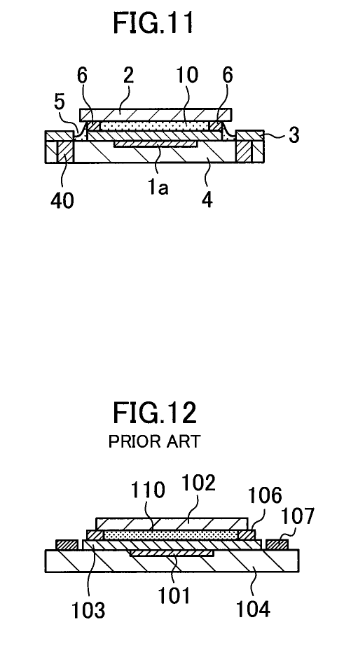

FIG. 11 is a view in vertical section showing a configuration of a solid state imaging element according to the present embodiment. The vertical section in FIG. 11 is taken on a plane extending in correspondence with each one in FIGS. 2B and 4B.

As shown in FIG. 11, the solid state imaging element of the present embodiment includes a through electrodes or through vias 40 instead of the electrode pads 7, compared with the solid state imaging element according to the second embodiment as shown in FIGS. 4A through 4C.

In the solid state imaging element according to the present embodiment, a light transmitting insulator film 3 having recessed portions 5 formed therein is provided on a semiconductor substrate 4, and protruding portions 6 are formed in a region on the light transmitting insulator film 3 between a light receiving region 1a and the recessed portions 5. A light transmitting member 2 is bonded onto the light transmitting insulator film 3 through a light transmitting adhesive 10. On a back side of the semiconductor substrate 4, there are provided a plurality of external terminals (not shown) formed of solder or the like electrically connected to the through electrodes 40.

In furtherance thereto, the semiconductor substrate 4 has the through electrodes 40 extending through the semiconductor substrate 4 and connected to the circuit formed within the light receiving region 1a. Like the electrode pads 7, the through electrodes 40 may be arranged in a row on a peripheral portion of the semiconductor substrate 4, for example.

Since the solid state imaging element including the through electrodes 40 does not include any electrode pads 7, it is of no problem if the light transmitting adhesive 10 flows above the through electrodes 40. However, if the light transmitting adhesive 10 flows around to a lateral side each of the semiconductor substrate 4, it may cause a connection failure or other troubles occurring on the underside each of the through electrodes 40.

In case of the solid state imaging element according to the present embodiment, however, since the recessed portions 5 are formed outside the protruding portion 6, the recessed portions 5 may retain the light transmitting adhesive 10 therein even if the light transmitting adhesive 10 cannot be stopped by the protruding portion 6. Thus, it is possible to effectively prevent the light transmitting adhesive 10 from flowing around to the lateral side of the semiconductor substrate 4.

Since the light transmitting adhesive 10 may be provided above the through electrodes 40, the size of the solid state imaging element as viewed from above can be reduced, compared with the solid state imaging element providing the electrode pads, without changing the size of the light receiving element 1a.

In particular, in the solid state imaging element according to the present embodiment, since the recessed portions 5 are formed outside the protruding portion 6, a margin for effectively preventing the light transmitting adhesive 10 from flowing around to the lateral side of the semiconductor substrate 4 can be set small, which further reduces the size of the solid state imaging element as viewed from above.

In furtherance thereto, since the recessed portions 5 are formed outside the protruding portion 6, it is easy to fill the light transmitting adhesive 10 between the light transmitting insulator film 3 and the light transmitting member 2 without generating the voids. Thus, it is possible to make uniform an incident efficiency of light which is incident to the light receiving region 1a.

### Other Embodiments

Without departing from the scope and spirit of the present invention, combining a plurality of the embodiments can be done regarding the shapes of the protruding portion 6 and the recessed portion 5 and so on. For instance, the recessed portion 5, having its wall forming an inclined side, can be provided to the solid state imaging element having the through elements. And, the recessed portion 5, having its wall forming an inclined side, can be provided to another solid state imaging element having a plurality of protruding portions at a distance one from another.

In still furtherance thereto, the shape each of the protruding portion 6 and the recessed portion 5 and the size each of the components and so on having described in the present specification are provided for the exemplifying purpose only. These can be modified so long as this does not depart from the scope and spirit of the present invention. For instance, in the solid state imaging element according to the first through third embodiments, additional protruding portions and additional recessed portions may be provided on the edge regions of the semiconductor substrate 4 extending along the side(s) not arranging the electrode pads 7. In the foregoing embodiments, the electrode pads 7 are provided only on two opposite sides of the solid state imaging device, but this is not limitative. Instead, the electrode pads 7 may be arranged on all of the four sides of the solid state imaging device, or the electrode pads 7 may be arranged on three sides of the solid state imaging device.

As described above, an optical device according to the present invention as exemplified, described and shown has its utility and application to reduction in size and sensitivity enhancement of the optical device.

What is claimed is:

1. An optical device comprising:
a semiconductor substrate having an element region formed on an upper side thereof, the element region including at least one of a light receiving region and a light emitting region;
at least one recessed portion located in a region outside the element region;
at least one protruding portion provided in a region outside the element region and inside the recessed portion;
a light transmitting member covering the element region from above, the light transmitting member being provided on the protruding portion; and
a light transmitting adhesive provided between the element region and the light transmitting member.

2. The optical device according to claim 1, further comprising:
a light transmitting insulator film covering the element region;
the recessed portion being formed in the light transmitting insulator film; and
the protruding portion being formed on the light transmitting insulator film.

3. The optical device according to claim 1, wherein
the recessed portion has a plurality of walls, and at least one of the walls closer to the element region forms an inclined side for reducing a width of the recessed portion as the one wall extends downward.

4. The optical device according to claim 1, wherein
the protruding portion has a trapezoidal shape in vertical section taken in a direction extending through the element region and the recessed portion and also extending normal to the upper side of the semiconductor substrate.

5. The optical device according to claim 1, further comprising:
one electrode pad or a plurality of electrode pads is/are provided in a region on the upper side of the semiconductor substrate and outside the recessed portion as viewed from the element region.

6. The optical device according to claim 5, wherein
the plurality of the electrode pads are arranged in a row; and
each of the recessed portion and the protruding portion is formed to extend along a direction in which the electrode pads are arranged.

7. The optical device according to claim 6, wherein
the protruding portion is provided only one for one row of the electrode pads.

8. The optical device according to claim 6, wherein
a plurality of the protruding portions are provided for one row of the electrode pads at a distance between the adjacent pair of the protruding portions.

9. The optical device according to claim 8, wherein
the distance between the adjacent pair of the protruding portions becomes smaller as the protruding portions extend from the element region toward the row of the electrode pads.

10. The optical device according to claim 6, wherein
the recessed portion is provided only one for one row of the electrode pads.

11. The optical device according to claim 6, wherein
a plurality of the recessed portions are provided for one row of the electrode pads.

12. The optical device according to claim 1, further comprising:
a through electrode located outside the element region and extending through the semiconductor substrate.

13. The optical device according to claim 1, wherein the element region comprises a light receiving region.

14. The optical device according to claim 1, wherein the element region comprises a light emitting region.

15. The optical device according to claim 1, wherein the light transmitting adhesive is present in the recessed portion also.

16. A method of manufacturing an optical device, comprising the steps of:
preparing a semiconductor substrate having an element region formed on an upper side thereof, the element region including at least one of a light receiving region and a light emitting region, and forming a light transmitting insulator film on the semiconductor substrate for covering the element region from above;
forming at least one recessed portion in a region of the light transmitting insulator film located outside the element region;
after the step of forming the recessed portion, forming at least one protruding portion provided on a region of the light transmitting insulator film located outside the element region and inside the recessed portion;
after the step of forming the protruding portion, applying a light transmitting adhesive in the liquid state onto the light transmitting insulator film; and
after the step of applying the light transmitting adhesive, placing a light transmitting member on the light transmitting insulator film to come into contact with the protruding portion and cover the element region from above, and curing the light transmitting adhesive, thereby bonding the light transmitting member to the light transmitting insulator film via a layer of the light transmitting adhesive.

17. The method of manufacturing an optical device according to claim 16, wherein
during the step of applying the light transmitting adhesive, the light transmitting adhesive is applied in an amount more than necessary to fill a space between the light transmitting member and the light transmitting insulator film.

18. The method of manufacturing an optical device according to claim 16, wherein
the recessed portion has a plurality of walls, and during the step of forming the recessed portion, at least one of the walls closer to the element region forms an inclined side for reducing a width of the recessed portion as the one wall extends downward.

19. The method of manufacturing an optical device according to claim 16, wherein
during the step of forming the protruding portion, the protruding portion is formed to have a trapezoidal shape in vertical section taken in a direction extending through the element region and the recessed portion and also extending normal to the upper side of the semiconductor substrate.

20. The method of manufacturing an optical device according to claim 16, wherein
one electrode pad or a plurality of electrode pads is/are provided in a region on the upper side of the semiconductor substrate prepared prior to the step of forming the recessed portion and outside the recessed portion as viewed from the element region.
